(19) United States
(12) Patent Application Publication
(10) Pub. No.: US 2021/0333639 A1
(43) Pub. Date: Oct. 28, 2021

(54) BACKLIGHT STRUCTURE AND DISPLAY PANEL

(71) Applicant: HUIZHOU CHINA STAR OPTOELECTRONICS TECHNOLOGY CO., LTD., Huizhou, Guangdong (CN)

(72) Inventor: Yongyuan QIU, Huizhou (CN)

(73) Assignee: Huizhou China Star Optoelectronics Technology Co., Ltd., Huizhou, Guangdong (CN)

(21) Appl. No.: 16/619,092

(22) PCT Filed: Jul. 12, 2019
(86) PCT No.: PCT/CN2019/095874

§ 371 Date: Dec. 4, 2019

(30) Foreign Application Priority Data
May 28, 2019 (CN) 201910450654.7

(51) Int. Cl. G02F 1/1335; H01L 25/075; G02F 1/13357

(52) U.S. Cl. CPC G02F 1/133607; G02F 1/133605; G02F 1/133603; H01L 25/0753

(57) ABSTRACT

A backlight structure and a display panel. The backlight structure includes a backlight source and a microlens array. The microlens array includes a support plate including a first surface and a second surface, the first surface having a plurality of light incident structures, and the second surface has a plurality of light emitting structures corresponding to the plurality of light incident structures, the plurality of light incident structures are press-formed on the first surface by a first mold, and the plurality of light emitting structures are press-formed on the second surface by a second mold.

### BACKGROUND OF INVENTION

### Field of Invention

The present invention relates to the field of display technologies, and in particular, to a backlight structure and a display panel.

### Description of Prior Art

Sub-millimeter light-emitting diodes (mini-LED) greatly reduce the size of a backlight source in a liquid crystal panel so that the size of backlight units can be less than 100 micrometers and the backlight sources can be thinned, miniaturized, and arrayed. Each pixel of a liquid crystal panel using the mini-LEDs can be addressed and driven individually.

### Technical Problem

Because the current microlens structure is too large to be used in the mini-LED backlight structure and microlens arrays realized by injection molding generally have a small area, there is an urgent need for a microlens structure suitable for mini-LEDs to further improve the light diffusion effect of the mini-LEDs and reduce the number of mini-LEDs to reduce the cost.

### SUMMARY OF INVENTION

The present application provides a backlight structure and a display panel, the backlight structure is provided with a microlens structure suitable for Mini-LEDs.

To solve the above problems, the present application provides a backlight structure, wherein the backlight structure comprises:

a backlight source;

a microlens array disposed on the backlight source;

wherein the microlens array comprises a support plate, the support plate comprises a first surface adjacent to the backlight source and a second surface away from the backlight source, the first surface has a plurality of light incident structures, and the second surface has a plurality of light emitting structures corresponding to the plurality of light incident structures, the light incident structures and the light emitting structures corresponding to the light incident structures constitute a plurality of microlens structures;

wherein the light incident structures are press-formed on the first surface by a first mold, the light emitting structures are press-formed on the second surface by a second mold;

wherein the microlens structures are arranged in a strip-shape along a first direction.

According to one aspect of the application, wherein the backlight source comprises a plurality of micro light emitting diodes disposed on a light board, the micro light emitting diodes are in one-to-one correspondence with the plurality of microlens structures.

According to one aspect of the application, wherein each of the light incident structures comprises a first protrusion structure;

wherein the first protrusion structure has a first surface in contact with a surface of the light board;

the first protrusion structure further comprises a first recessed portion disposed at a geometric center of the first surface, the first recessed portion corresponding to the micro light emitting diode, and a surface of the first recessed portion constitutes a light incident surface of the microlens structure.

According to one aspect of the application, wherein the first recess is a hemispherical structure, and the micro light emitting diode corresponding to the light incident structure is disposed at a center of the hemispherical structure.

The backlight structure according to claim 3, wherein each of the light emitting structures comprises a second protrusion structure;

wherein the second protruding structure has a second recessed portion disposed at a geometric center of the second protrusion structure, a geometric center of the second protrusion structure overlaps with a geometric center of the first protrusion structure;

wherein the second protrusion structure further comprises a second annular portion surrounding the second recessed portion, a surface of the second annular portion is a smooth curved surface connecting a boundary of the second recess and a surface of the support plate.

According to one aspect of the application, wherein a material forming the support plate, the first protrusion structure, and the second protrusion structure is a transparent material, and the transparent material has thermoplastic material.

According to one aspect of the application, wherein a surface of the second recessed portion is a mirror structure consisted of a reflective material, the surface of the second recessed portion constitutes a reflective surface of the microlens structure, a surface of the second annular portion constitutes a light emitting surface of the microlens structure.

According to one aspect of the application, wherein geometric centers of the first recessed portion and the second recessed portion overlap, a projection of the first recessed portion on the support plate and a projection of the second recessed portion on the support plate are circular, the projection of the first recessed portion on the support plate covers the projection of the second recessed portion on the support plate.

According to one aspect of the application, wherein the microlens array further comprises a plurality of support columns disposed on the second surface of the support plate, and each support column is located between two adjacent microlens structures.

According to one aspect of the application, wherein the plurality of support columns have a same height, and surfaces of the support columns have a diffuse reflection structure.

The present application further provides a backlight structure, wherein the backlight structure comprises:

a backlight source;

a microlens array disposed on the backlight source;

wherein the microlens array comprises a support plate, the support plate comprises a first surface adjacent to the backlight source and a second surface away from the backlight source, the first surface has a plurality of light incident structures, and the second surface has a plurality of light emitting structures corresponding to the plurality of light incident structures, the light incident structures and the light emitting structures corresponding to the light incident structures constitute a plurality of microlens structures;

wherein the light incident structures are press-formed on the first surface by a first mold, the light emitting structures are press-formed on the second surface by a second mold.

According to one aspect of the application, wherein the backlight source comprises a plurality of micro light emitting diodes disposed on a light board, the micro light emitting diodes are in one-to-one correspondence with the plurality of microlens structures.

According to one aspect of the application, wherein each of the light incident structures comprises a first protrusion structure;

wherein the first protrusion structure has a first surface in contact with a surface of the light board;

the first protrusion structure further comprises a first recessed portion disposed at a geometric center of the first surface, the first recessed portion corresponding to the micro light emitting diode, and a surface of the first recessed portion constitutes a light incident surface of the microlens structure.

According to one aspect of the application, wherein the first recess is a hemispherical structure, and the micro light emitting diode corresponding to the light incident structure is disposed at a center of the hemispherical structure.

According to one aspect of the application, wherein each of the light emitting structures comprises a second protrusion structure;

wherein the second protruding structure has a second recessed portion disposed at a geometric center of the second protrusion structure, a geometric center of the second protrusion structure overlaps with a geometric center of the first protrusion structure;

wherein the second protrusion structure further comprises a second annular portion surrounding the second recessed portion, a surface of the second annular portion is a smooth curved surface connecting a boundary of the second recess and a surface of the support plate.

The backlight structure according to claim 15, wherein a material forming the support plate, the first protrusion structure, and the second protrusion structure is a transparent material, and the transparent material has thermoplastic material.

According to one aspect of the application, wherein a surface of the second recessed portion is a mirror structure consisted of a reflective material, the surface of the second recessed portion constitutes a reflective surface of the microlens structure, a surface of the second annular portion constitutes a light emitting surface of the microlens structure.

According to one aspect of the application, wherein geometric centers of the first recessed portion and the second recessed portion overlap, a projection of the first recessed portion on the support plate and a projection of the second recessed portion on the support plate are circular, the projection of the first recessed portion on the support plate covers the projection of the second recessed portion on the support plate.

According to one aspect of the application, wherein the microlens array further comprises a plurality of support columns disposed on the second surface of the support plate, and each support column is located between two adjacent microlens structures.

The present application further provides a display panel comprising a backlight structure, wherein the backlight structure comprises:

a backlight source;

a microlens array disposed on the backlight source;

wherein the microlens array comprises a support plate, the support plate comprises a first surface adjacent to the backlight source and a second surface away from the backlight source, the first surface has a plurality of light incident structures, and the second surface has a plurality of light emitting structures corresponding to the plurality of light incident structures, the light incident structures and the light emitting structures corresponding to the light incident structures constitute a plurality of microlens structures;

wherein the light incident structures are press-formed on the first surface by a first mold, the light emitting structures are press-formed on the second surface by a second mold.

### Beneficial Effects

The application provides a backlight structure having a support plate, a first surface of the support plate has a plurality of light incident structures, a second surface of the support plate has a plurality of light emitting structures corresponding to the plurality of light incident structures. The plurality of light incident structures and the plurality of light emitting structures form a plurality of microlens structures. In the present application, the plurality of light incident structures and the plurality of light emitting structures are formed by different molds. The microlens array provided by the present application is press-formed and can form a large-area microlens array suitable for mini-LEDs, thereby solving the technical problem that the microlens array in the prior art cannot be applied to the mini-LEDs.

### BRIEF DESCRIPTION OF DRAWINGS

FIG. 1 is a structural diagram of a microlens array in a specific embodiment of the present application.

FIG. 2 is a structural diagram of a microlens in the microlens array of FIG. 1.

FIG. 3 is a structural diagram of a backlight structure in a specific embodiment of the present application.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

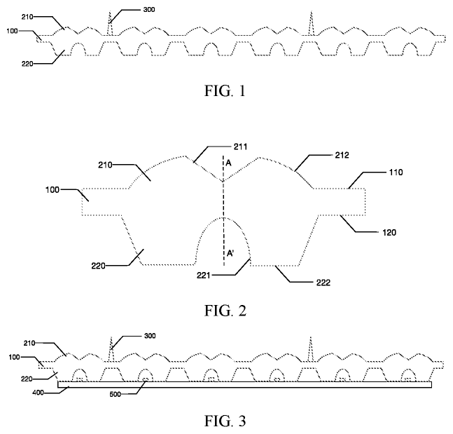

The present application provides a backlight structure and a display panel, the backlight structure is provided with a microlens structure suitable for mini-LEDs. Referring to FIG. 1, FIG. 2 and FIG. 3, FIG. 1 is a structural diagram of a microlens array in a specific embodiment of the present application, FIG. 2 is a structural diagram of a microlens in the microlens array of FIG. 1, FIG. 3 is a structural diagram of a backlight structure in a specific embodiment of the present application.

As shown in FIG. 3, the backlight structure includes a backlight source and a microlens array disposed on the backlight source. The microlens array includes a support plate 100, the support plate 100 includes a first surface adjacent to the backlight source and a second surface away from the backlight source, the first surface has a plurality of light incident structures 220, and the second surface has a plurality of light emitting structures 210 corresponding to the plurality of light incident structures 220, the light incident structures 220 and the light emitting structures 210 corresponding to the light incident structures 220 constitute a plurality of microlens structures.

In the present embodiment, the light incident structures 220 are press-formed on the first surface by a first mold, the light emitting structures 210 are press-formed on the second surface by a second mold.

The backlight source comprises a plurality of micro light emitting diodes 400 disposed on a light board 500. Preferably, the backlight source comprises a plurality of light panels 500, the light boards 500 are strip light boards and the plurality of micro light emitting diodes 400 are arranged in a strip shape in a first direction. The plurality of light panels 500 are arranged in a second direction perpendicular to the first direction. The micro light emitting diodes 400 are in one-to-one correspondence with the plurality of microlens structures.

Referring to FIG. 2, in the present application, each of the light incident structures 220 comprises a first protrusion structure. The first protrusion structure has a first surface 222 in contact with a surface of the light board 500. The first protrusion structure further comprises a first recessed portion 221 disposed at a geometric center of the first surface, the first recessed portion 221 corresponding to the micro light emitting diode, and a surface of the first recessed portion 221 constitutes a light incident surface of the microlens structure.

In the present application, the first recess 221 is a hemispherical structure, and the micro light emitting diode corresponding to the light incident structure 220 is disposed at a center of the hemispherical structure.

In the present application, each of the light emitting structures 220 includes a second protrusion structure. The second protruding structure has a second recessed portion 211 disposed at a geometric center of the second protrusion structure, a geometric center A of the second protrusion structure overlaps with a geometric center of the first protrusion structure.

In the present embodiment, the second protrusion structure further comprises a second annular portion 212 surrounding the second recessed portion, a surface of the second annular portion 212 is a smooth curved surface connecting a boundary of the second recess 211 and a surface of the support plate 100.

In the present application, a material forming the support plate 100, the first protrusion structure, and the second protrusion structure is a transparent material, and the transparent material has thermoplastic material.

Because the size of the micro light-emitting diodes is small, the method in the prior art of producing a lens array cannot produce millimeter-scale microlenses. In the present application, a transparent material having thermoplasticity is used and a microlens array is formed by imprinting a surface of the transparent material through a mold. This method enables a formation of microlens arrays with various shapes and sizes to meet the requirements of micro light-emitting diodes. At the same time, the method is simple in process, low in cost, convenient for mass production, and can greatly improve the light mixing effect of the backlight structure using micro light-emitting diodes.

In the present application, a surface of the second recessed portion 211 is a mirror structure consisted of a reflective material, the surface of the second recessed portion constitutes a reflective surface of the microlens structure, a surface of the second annular portion 212 constitutes a light emitting surface of the microlens structure. Geometric centers of the first recessed portion 221 and the second recessed portion 211 overlap, a projection of the first recessed portion 221 on the support plate and a projection of the second recessed portion 211 on the support plate are circular, the projection of the first recessed portion 221 on the support plate covers the projection of the second recessed portion 211 on the support plate.

In the present embodiment, the microlens array further includes a plurality of support columns 300 disposed on the second surface of the support plate 100, and each support column 300 is located between two adjacent microlens structures.

In this embodiment, the support columns 300 have a same height. On one hand, it is used to disperse pressure applied to the microlens array by other optical films, and the microlens array can be protected of being cracked due to uneven force. On the other hand, it is also possible to ensure that the distance between the microlens array and other optical films remains constant. Preferably, in order to prevent the support columns 300 from forming spots or shadows on the display panel, the materials forming the plurality of support pillars 300 are white materials or transparent materials, and the surfaces of the plurality of support pillars 300 have a diffuse reflection structure.

Further, the present application provides a display panel including the backlight structure described above.

The application provides a backlight structure having a support plate, a first surface of the support plate has a plurality of light incident structures, a second surface of the support plate has a plurality of light emitting structures corresponding to the plurality of light incident structures. The plurality of light incident structures and the plurality of light emitting structures form a plurality of microlens structures. In the present application, the plurality of light incident structures and the plurality of light emitting structures are formed by different molds. The microlens array provided by the present application is press-formed and can form a large-area microlens array suitable for mini-LEDs, thereby solving the technical problem that the microlens array in the prior art cannot be applied to the mini-LEDs.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

1. A backlight structure, wherein the backlight structure comprises:
a backlight source;
a microlens array disposed on the backlight source;
wherein the microlens array comprises a support plate, the support plate comprises a first surface adjacent to the backlight source and a second surface away from the backlight source, the first surface has a plurality of light incident structures, and the second surface has a plurality of light emitting structures corresponding to the plurality of light incident structures, the light incident structures and the light emitting structures corresponding to the light incident structures constitute a plurality of microlens structures;
wherein the microlens structures are arranged in a strip-shape along a first direction.

2. The backlight structure according to claim 1, wherein the backlight source comprises a plurality of micro light emitting diodes disposed on a light board, the micro light emitting diodes are in one-to-one correspondence with the plurality of microlens structures.

3. The backlight structure according to claim 2, wherein each of the light incident structures comprises a first protrusion structure;
wherein the first protrusion structure has a first surface in contact with a surface of the light board;
the first protrusion structure further comprises a first recessed portion disposed at a geometric center of the first surface, the first recessed portion corresponding to the micro light emitting diode, and a surface of the first recessed portion constitutes a light incident surface of the microlens structure.

4. The backlight structure according to claim 3, wherein the first recess is a hemispherical structure, and the micro light emitting diode corresponding to the light incident structure is disposed at a center of the hemispherical structure.

5. The backlight structure according to claim 3, wherein each of the light emitting structures comprises a second protrusion structure;
wherein the second protruding structure has a second recessed portion disposed at a geometric center of the second protrusion structure, a geometric center of the second protrusion structure overlaps with a geometric center of the first protrusion structure;
wherein the second protrusion structure further comprises a second annular portion surrounding the second recessed portion, a surface of the second annular portion is a smooth curved surface connecting a boundary of the second recess and a surface of the support plate.

6. The backlight structure according to claim 5, wherein a material forming the support plate, the first protrusion structure, and the second protrusion structure is a transparent material, and the transparent material has thermoplastic material.

7. The backlight structure according to claim 6, wherein a surface of the second recessed portion is a mirror structure consisted of a reflective material, the surface of the second recessed portion constitutes a reflective surface of the microlens structure, a surface of the second annular portion constitutes a light emitting surface of the microlens structure.

8. The backlight structure according to claim 5, wherein geometric centers of the first recessed portion and the second recessed portion overlap, a projection of the first recessed portion on the support plate and a projection of the second recessed portion on the support plate are circular, the projection of the first recessed portion on the support plate covers the projection of the second recessed portion on the support plate.

9. The backlight structure according to claim 1, wherein the microlens array further comprises a plurality of support columns disposed on the second surface of the support plate, and each support column is located between two adjacent microlens structures.

10. The backlight structure of claim 9, wherein the plurality of support columns have a same height, and surfaces of the support columns have a diffuse reflection structure.

11. A backlight structure, wherein the backlight structure comprises:
a backlight source;
a microlens array disposed on the backlight source;
wherein the microlens array comprises a support plate, the support plate comprises a first surface adjacent to the backlight source and a second surface away from the backlight source, the first surface has a plurality of light incident structures, and the second surface has a plurality of light emitting structures corresponding to the plurality of light incident structures, the light incident structures and the light emitting structures corresponding to the light incident structures constitute a plurality of microlens structures.

12. The backlight structure according to claim 11, wherein the backlight source comprises a plurality of micro light emitting diodes disposed on a light board, the micro light emitting diodes are in one-to-one correspondence with the plurality of microlens structures.

13. The backlight structure according to claim 12, wherein each of the light incident structures comprises a first protrusion structure;
wherein the first protrusion structure has a first surface in contact with a surface of the light board;
the first protrusion structure further comprises a first recessed portion disposed at a geometric center of the first surface, the first recessed portion corresponding to the micro light emitting diode, and a surface of the first recessed portion constitutes a light incident surface of the microlens structure.

14. The backlight structure according to claim 13, wherein the first recess is a hemispherical structure, and the micro light emitting diode corresponding to the light incident structure is disposed at a center of the hemispherical structure.

15. The backlight structure according to claim 13, wherein each of the light emitting structures comprises a second protrusion structure;
wherein the second protruding structure has a second recessed portion disposed at a geometric center of the second protrusion structure, a geometric center of the second protrusion structure overlaps with a geometric center of the first protrusion structure;
wherein the second protrusion structure further comprises a second annular portion surrounding the second recessed portion, a surface of the second annular portion is a smooth curved surface connecting a boundary of the second recess and a surface of the support plate.

16. The backlight structure according to claim 15, wherein a material forming the support plate, the first protrusion structure, and the second protrusion structure is a transparent material, and the transparent material has thermoplastic material.

17. The backlight structure according to claim 16, wherein a surface of the second recessed portion is a mirror structure consisted of a reflective material, the surface of the second recessed portion constitutes a reflective surface of the microlens structure, a surface of the second annular portion constitutes a light emitting surface of the microlens structure.

18. The backlight structure according to claim 15, wherein geometric centers of the first recessed portion and the second recessed portion overlap, a projection of the first recessed portion on the support plate and a projection of the second recessed portion on the support plate are circular, the projection of the first recessed portion on the support plate covers the projection of the second recessed portion on the support plate.

19. The backlight structure according to claim 11, wherein the microlens array further comprises a plurality of support columns disposed on the second surface of the support plate, and each support column is located between two adjacent microlens structures.

20. A display panel comprising a backlight structure, wherein the backlight structure comprises:
a backlight source;
a microlens array disposed on the backlight source;
wherein the microlens array comprises a support plate, the support plate comprises a first surface adjacent to the backlight source and a second surface away from the backlight source, the first surface has a plurality of light incident structures, and the second surface has a plurality of light emitting structures corresponding to the plurality of light incident structures, the light incident structures and the light emitting structures corresponding to the light incident structures constitute a plurality of microlens structures;
wherein the light incident structures are press-formed on the first surface by a first mold, the light emitting structures are press-formed on the second surface by a second mold.
